(19) United States
(12) Patent Application Publication
(10) Pub. No.: US 2024/0290807 A1
(43) Pub. Date: Aug. 29, 2024

(54) SUBSTRATELESS CHIP SCALE OPTICAL SENSOR PACKAGE

(71) Applicant: STMicroelectronics International N.V., Geneva (CH)

(72) Inventor: Jing-En LUAN, Singapore (SG)

(73) Assignee: STMicroelectronics International N.V., Geneva (CH)

(21) Appl. No.: 18/415,231

(22) Filed: Jan. 17, 2024

Related U.S. Application Data
(60) Provisional application No. 63/447,971, filed on Feb. 24, 2023.

(51) Int. Cl. H01L 27/146; H01L 23/31

(52) U.S. Cl. CPC H01L 27/14625; H01L 23/3171; H01L 27/14618; H01L 27/14636; H01L 27/14685

(57) ABSTRACT

A body of laser direct structuring (LDS) encapsulating material encapsulates an integrated circuit device and an optical element mounted thereto. Laser activated trace regions and via openings at a first surface of the body are plated to form first conductive lines and first conductive vias. A first passivation layer covers the first conductive lines, the first surface of the body and a portion of the optical element. A second passivation layer covers a thinned backside of the body and integrated circuit device where distal ends of the first conductive vias are exposed. A redistribution layer (RDL) at the second passivation layer includes second conductive lines, pads, and second conductive vias which extend through the second passivation layer to electrically connect the second conductive lines to the distal ends of the first conductive vias. A solder mask layer on the second passivation layer includes openings at the pads of the RDL.

### CROSS REFERENCE TO RELATED APPLICATIONS

This application claims priority from United States Provisional Application for Patent No. 63/447,971, filed Feb. 24, 2023, the disclosure of which is incorporated herein by reference.

### TECHNICAL FIELD

The present invention generally relates to semiconductor packaging and, more particularly, to the packaging of an optical semiconductor device.

### BACKGROUND

Reference is made to FIG. 1 which shows a cross sectional view of a conventional packaging configuration for an optical integrated circuit sensor device 10. The device 10 includes a first side 12 and an opposed second side 14 with a peripheral side edge 16. The first side 12 of the device 10 includes an optical sensor 18 and a plurality of electrical connection pads 20 (referred to in the art as bonding pads). The second side 14 of the device 10 is attached to the upper surface 22 of a support substrate 24. The upper surface 22 of the support substrate 24 includes a plurality of electrical connection pads 26 (referred to in the art as bonding fingers). The electrical connection pads 20 of the device 10 are electrically connected to the electrical connection pads 26 of the support substrate 24 using bonding wires 28. The lower surface 30 of the support substrate 24 also includes a plurality of electrical connection pads 32. The electrical connection pads 26 are electrically connected to the electrical connection pads 32 using an interconnection network 34 formed within the support substrate 24. The interconnection network 34 includes one or more layers of interconnection lines 36 and vias 38. An optical element 40 is mounted to the first side 12 of the device 10 to extend over the optical sensor 18. This mounting is accomplished through the use of an adhesive spacer ring 42 that surrounds the optical sensor 18 and is positioned between the optical element and the first side 12. The spacer ring 42 may, for example, comprise a bead of epoxy material deposited in a ring shape around the optical sensor 18. A first body 44 of an encapsulating material, referred to in the art as an underfill material, is used to encapsulate the device 10, bonding wires 28, optical element 40 and spacer ring 42. It will be noted that the spacer ring 42 prevents encapsulating material from encroaching on the optical sensor 18 at the first side 12 of the device 10. A second body 46 of an encapsulating material, typically different from the encapsulating material used for the first body 44 and comprising, for example, a resin, is provided as a package encapsulant using a molding operation. The plurality of electrical connection pads 32 at the lower surface 30 of the support substrate 24 are arranged in an array of rows and columns. A solder ball 50 may be included at each electrical connection pad 32.

FIG. 2 illustrates another embodiment of the optical integrated circuit sensor device 10. Like references in FIGS. 1 and 2 refer to same or similar components, the description of which will not be repeated. The embodiment of FIG. 2 differs from the embodiment of FIG. 1 primarily with respect to the configuration of the encapsulation. In the FIG. 2 embodiment, the underfill provided by the first body 44 of encapsulating material is omitted, and the molded resin material is used to provide the body 46 which encapsulates the device 10, bonding wires 28, optical element 40 and spacer ring 42.

While the embodiments for the packaging configuration for the optical integrated circuit sensor device 10 as shown in FIGS. 1 and 2 are widely used for consumer products and automotive applications, it is noted that these conventional packaging configurations suffer from many challenges and issues. For example, there are concerns with instances of cracks 60 forming in the optical element 40 (as shown in FIG. 3A), as well as delaminations 62 occurring at the first side 12 of the device 10 (as shown in FIG. 3B). These issues arise as a result of stress induced by coefficient of thermal expansion mismatch between the encapsulation materials and the optical element as well as between the integrated circuit and the support substrate. An additional concern with the packaging configurations shown in FIGS. 1 and 2 is the large form factor of the package both in the x-y plane (parallel to the opposed surfaces of the integrated circuit) and the orthogonal z direction.

There is accordingly a need in the art to address the foregoing issues.

### SUMMARY

In an embodiment, an integrated circuit package comprises: an integrated circuit device having a first side and an opposed second side, with an optical sensor and first electrical connection pads at said first side; an optical element mounted to the first side of the integrated circuit device to extend over the optical sensor; a body of laser direct structuring (LDS) encapsulating material which encapsulates the integrated circuit device and the optical element, said body having a first surface coplanar with an upper surface of the optical element and a second surface coplanar with the second side of the integrated circuit device; wherein said body includes activated trace regions at the first surface, first activated via openings extending through the body from the first surface to the second surface, and second activated via openings extending into the body from the first surface to the first electrical connection pads; first conductive lines at said activated trace regions; first conductive vias at said first and second activated via openings in electrical connection with the first conductive lines; a first passivation layer covering the first conductive lines, the first surface of the body and a portion of the optical element; a second passivation layer covering the second surface of the body and the second side of the integrated circuit device; and a redistribution layer (RDL) including second conductive lines and second conductive vias which extend through the second passivation layer to electrically connect the second conductive lines to the first conductive vias.

In an embodiment, a method comprises: mounting a plurality of integrated circuit devices in a spaced apart fashion to a support handle; wherein an optical element is mounted to a first side of each integrated circuit device to extend over an optical sensor; molding a laser direct structuring (LDS) encapsulation material to form a body that encapsulates the plurality of integrated circuit devices and the optical elements mounted thereto; wherein a first surface of the body is coplanar with an upper surface of each of the optical elements; laser defining activated trace regions on the first surface of the body; laser drilling first activated via openings extending into the body from the first surface, said first activated via openings reaching electrical connection pads at the first side of the integrated circuit devices; laser drilling second activated via openings extending into the body from the first surface to a depth which does not reach a second surface of the body in contact with the support handle; plating conductive vias at the first and second activated via openings and plating conductive lines at the activated trace regions; depositing a first passivation layer to cover the first surface of the body, the conductive lines and a portion of the upper surface of the upper surface of each of the optical elements; removing the support handle to expose the second surface of the body and a second side of each integrated circuit device opposite the first side; thinning the body from its second surface and each integrated circuit device from its second side to form a thinned surface at which a distal end of the conductive vias at the second activated via openings is exposed; depositing a second passivation layer to cover the thinned surface; and forming a redistribution layer (RDL) including second conductive lines and second conductive vias which extend through the second passivation layer to electrically connect the second conductive lines to the distal end of the conductive vias at the second activated via openings.

### BRIEF DESCRIPTION OF THE DRAWINGS

For a better understanding of the embodiments, reference will now be made by way of example only to the accompanying figures in which:

FIGS. 1 and 2 show a cross-sectional views of a conventional packaging configuration for an optical integrated circuit sensor device;

FIGS. 3A and 3B illustrate defects which may arise in connection with the conventional packaging configurations of FIGS. 1 and 2;

FIG. 4 shows a cross-sectional view of an embodiment for an optical integrated circuit sensor device packaging configuration;

FIGS. 5A-5M show steps in a method for manufacturing the optical integrated circuit sensor device packaging configuration shown in FIG. 4; and

FIG. 6 shows a cross sectional diagram of an imaging sensor product utilizing the optical integrated circuit sensor device packaging configuration shown in FIG. 4.

### DETAILED DESCRIPTION

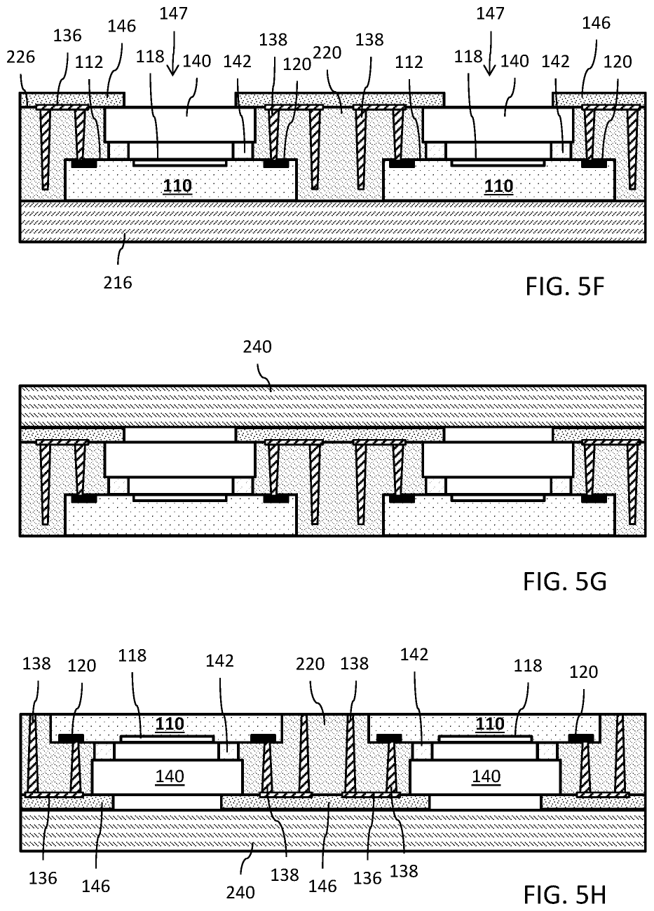

Reference is made to FIG. 4 which shows a cross sectional view of a packaging configuration for an embodiment of an optical integrated circuit sensor device 110. The device 110 includes a first side 112 and an opposed second side 114 with a peripheral side edge 116. The first side 112 of the device 110 includes an optical sensor 118 and a plurality of electrical connection pads 120 (referred to in the art as bonding pads). An optical element 140 is mounted to the first side 112 of the device 110 to extend over the optical sensor 118. This mounting is accomplished through the use of an adhesive spacer ring 142 that surrounds the optical sensor 118 and is positioned between the optical element and the first side 112. The spacer ring 142 may, for example, comprise a bead of epoxy material deposited in a ring shape around the optical sensor 118. A body 144 of a laser direct structuring (LDS) encapsulating material is used to encapsulate the device 110, optical element 140 and spacer ring 142. It will be noted that the spacer ring 142 prevents the LDS encapsulating material from encroaching on the optical sensor 118 at the first side 112 of the device 110. A first surface 143 of the body 144 is coplanar with the upper surface of the optical element 140, and a second surface 145 of the body 144 is coplanar with the second side 114 of the device 110. The LDS encapsulating material is structured by laser processing to define activated trace regions on the first surface 143 of the body 144 and activated via openings extending into the body 144 from the first surface 143. The activated trace regions define the locations for an electrical connection network. Using plating techniques, conductive lines 136 for the electrical connection network are formed at the activated trace regions and conductive vias 138 are formed at the activated via openings. The activated via openings include first openings for vias 138 extending into the body 144 from the first surface 143 to reach the electrical connection pads 120 of the device 110, with proximal ends of the vias 138 in electrical contact with the conductive lines 136 and distal ends of the vias 138 in electrical contact with the electrical connection pads 120. The activated via openings further include second openings, deeper than the first openings, for vias 138 extending into the body 144 from the first surface 143 to pass completely through the thickness of the body 144, with proximal ends of the vias 138 in electrical contact with the conductive lines 136. A first passivation layer 146 covers the first surface 143 of the body 144, the conductive lines 136 for the electrical connection network and a portion of the upper surface of the optical element 140. An opening 147 in the first passivation layer 146 exposes a central region of the optical element 140 that is optically aligned with the optical sensor 118. A second passivation layer 156 covers the second surface 145 of the body 144, and the second side 114 of the device 110. Using lithographic processing and metal deposition techniques, an electrical redistribution layer (RDL) is formed at the second passivation layer 156 to provide conductive lines 161, pads 162 and vias 163. The vias 163 extend through the second passivation layer 156 between the conductive lines 161 and distal ends of the vias 138 which pass through the body 144. The plurality of pads 162 of the electrical RDL are arranged in an array of rows and columns. A solder mask layer 170 covers the second passivation layer 156. Openings 172 are provided in the solder mask layer 170 at locations of the pads 162 for the electrical RDL. A solder ball 150 may be included within the opening 172 at each pad 162.

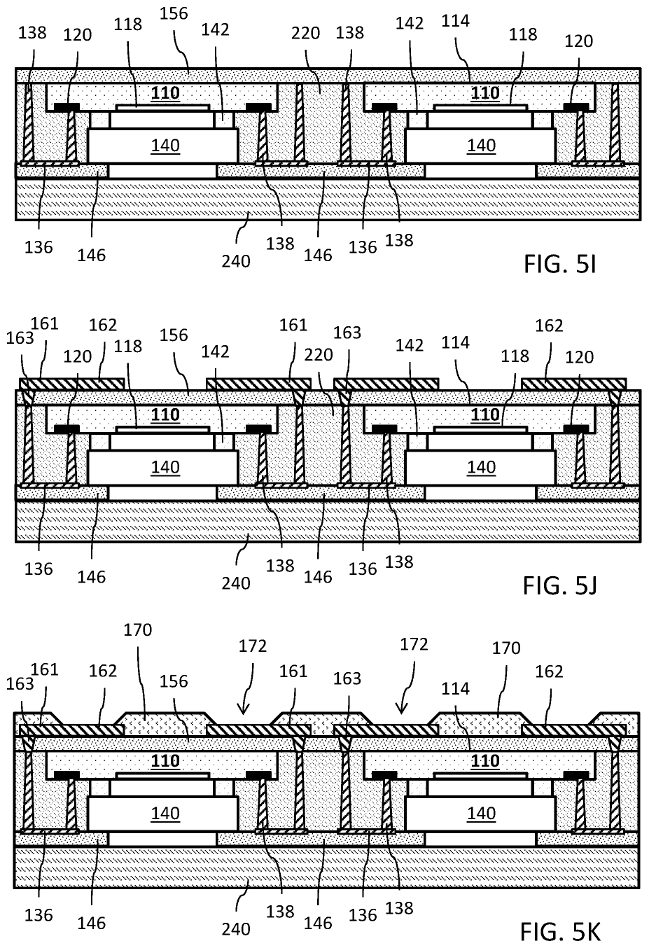

FIGS. 5A-5M show steps in a method for manufacturing the packaging configuration for the optical integrated circuit sensor device shown in FIG. 4.

FIG. 5A—an integrated circuit wafer 210 including a plurality of optical integrated circuit sensor devices is mounted to a first support handle 212 that is, for example, made of a glass material. Attachment of the wafer 210 to handle 212 may be made using any suitable adhesive layer. At the location of each optical sensor 118, an optical element 140 is mounted to the first side 112 using an adhesive spacer ring 142, with the optical element extending over the optical sensor 118. A wafer dicing operation is then performed to cut through the wafer 210 along scribe lines 214 which extend between locations of the integrated circuit sensor devices.

FIG. 5B—the singulated optical integrated circuit sensor devices 110, with the optical elements 140 and spacer rings 142 mounted thereto, that are produced by the wafer dicing operation in FIG. 5A are then mounted in a spaced apart fashion to a second support handle 216. Attachment of the singulated optical integrated circuit sensor devices 110 to the handle 216 may be made using any suitable adhesive layer.

FIG. 5C—the handle 216 with attached singulated optical integrated circuit sensor devices 110, optical elements 140 and spacer rings 142, is then placed within a molding cavity and a laser direct structuring (LDS) encapsulation material is injected in the molding cavity to produce an encapsulant body 220. This transfer molding process is well known in the art. The laser direct structuring encapsulation material may comprise, for example, a resin material infiltrated with laser activatable particles. Such an LDS encapsulation material is well known to those skilled in the art.

FIG. 5D—laser processing operations are then used for structuring to laser define activated trace regions 224 on the first surface 226 of the body 220 and laser drill activated via openings 228a, 228b extending into the body 220 from the first surface 226. Those of skill in the art are aware of the laser operation parameter requirements for activating LDS encapsulation material. It will be noted that the via openings 228a extend into the body 220 to a depth that reaches and exposes the electrical connection pads 120 of the device 110. The via openings 228b extend into the body 220 to a depth that is less than a thickness of the body 220. Those skilled in the art can control the laser operation parameters to set the desired depth for the laser drilled via openings.

FIG. 5E—using plating techniques, for example an electroless plating, conductive lines 136 for an electrical connection network are formed at the activated trace regions 224 and conductive vias 138 are formed at the activated via openings 228a, 228b.

FIG. 5F—a deposition is made of a first passivation layer 146 to cover the surface 226 of the body 220, the conductive lines 136 for the electrical connection network and a portion of the upper surface of the optical element 140. Using lithographic processing techniques, for example through use of a controlled etch, openings 147 are formed in the first passivation layer 146 to expose a central region of each optical element 140 in optical alignment with the optical sensor 118.

FIG. 5G—a handle 240 is then mounted to the first passivation layer 146. Attachment of the handle 240 to the first passivation layer 146 may be made using any suitable adhesive layer. The handle 216 is removed.

FIG. 5H—the processing orientation of assembly is then flipped 180° and a back grind process is performed to thin the body 220 and device 110 from their coplanar back side surfaces until the distal ends of the conductive vias 138 within the activated via openings 228b are exposed.

FIG. 5I—a deposition is made of a second passivation layer 156 to cover the second surface 114 of the thinned device 110 as well as a back surface of the thinned body 220.

FIG. 5J—using lithographic processing and metal deposition techniques (such as a via etch and fill followed by a metal layer deposition and patterning), an electrical redistribution layer (RDL) is formed at the second passivation layer 156 to provide conductive lines 161, pads 162 and vias 163. The vias 163 extend through the second passivation layer 156 between the conductive lines 161 and make electrical contact with distal ends of the vias 138 which pass through the thinned body 220. The conductive lines 161 make electrical contact with proximal ends of the vias 163 and extend over the surface of the second passivation layer 156.

FIG. 5K—a solder mask layer 170 is then deposited to cover the second passivation layer 156. Lithographic processing techniques (for example through a controlled etch) are used to form openings 172 in the solder mask layer 170 at locations of the pads 162 for the electrical RDL.

FIG. 5L—a solder ball 150 is then installed within each opening 172 on pad 162. A dicing operation is then performed to cut through the structure along singulation lines 260 which extend between locations of the integrated circuit sensor devices 110 to produce a plurality of the optical integrated circuit sensor device packages; one such device package being shown in FIGS. 4 and 5M. The handle 240 is also removed.

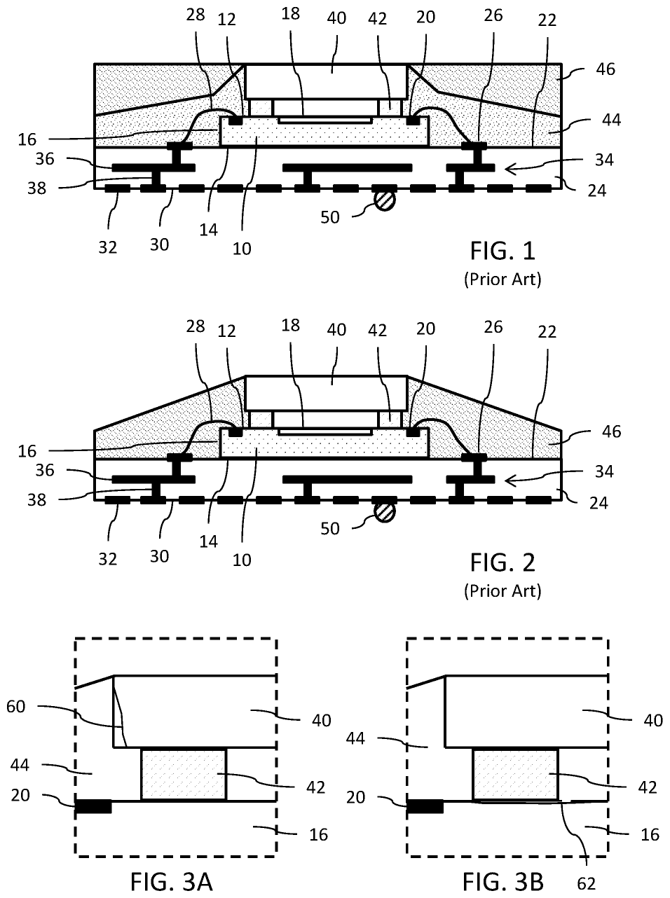

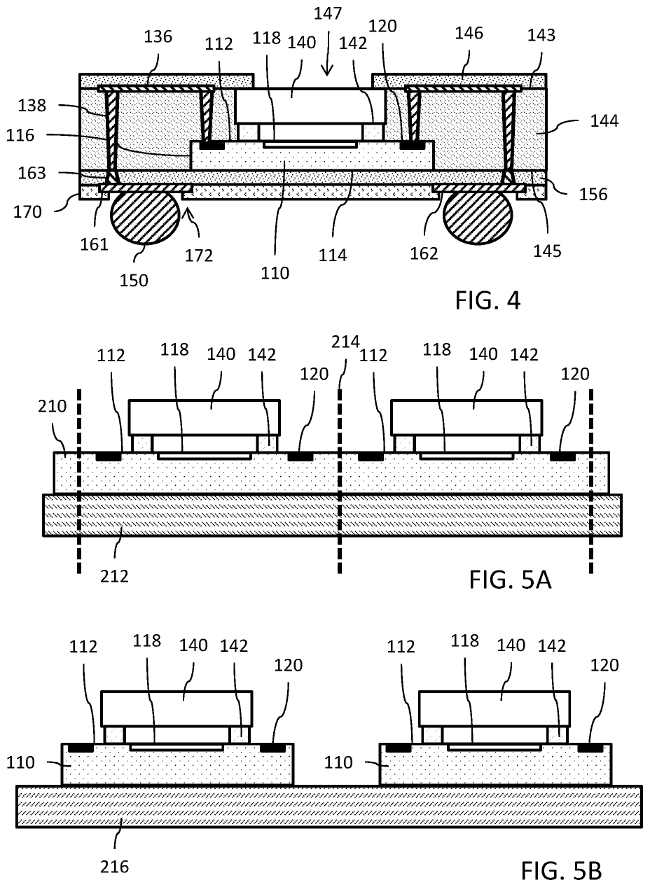

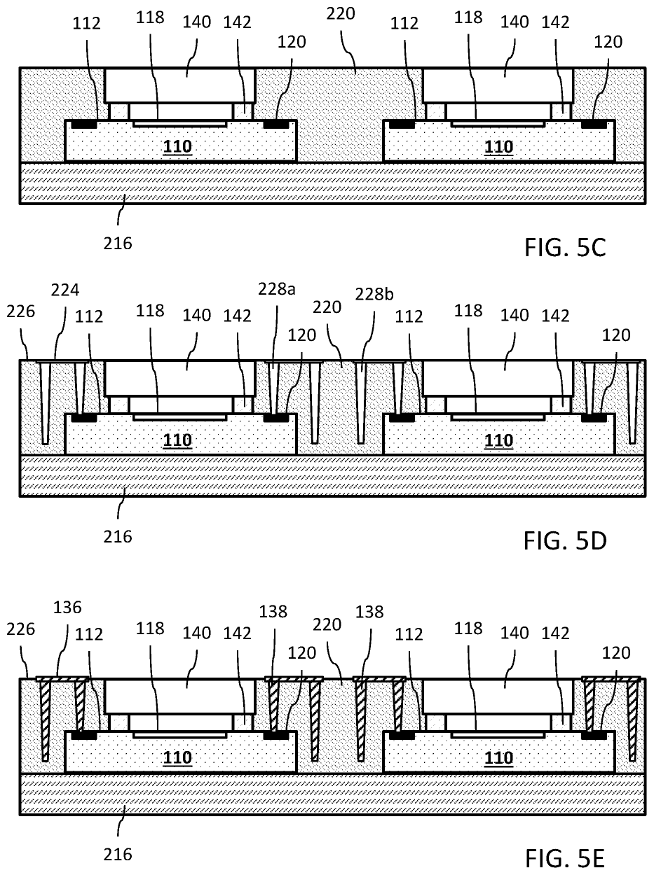

The optical integrated circuit sensor device packaging configuration shown in FIGS. 4 and 5M presents a number of advantages over the conventional packaging configurations shown in FIGS. 1 and 2, including: the use of a smaller form factor in the x-y plane (parallel to the opposed first, second surfaces of the integrated circuit sensor) due to the use of laser direct structured wiring and vias which occupy less area than wire bonds; the use of a smaller form factor in the orthogonal z direction due to the fact that no thick support substrate with electrical interconnections is needed; there is a reduction in stress concentration as the size is smaller and there is a lower coefficient of thermal expansion mismatch (and so the bending induced by the die/substrate thermal interaction is eliminated). The FIG. 4 packaging configuration also exhibits better optical, electrical and thermal performance in comparison to the packages of FIGS. 1 and 2.

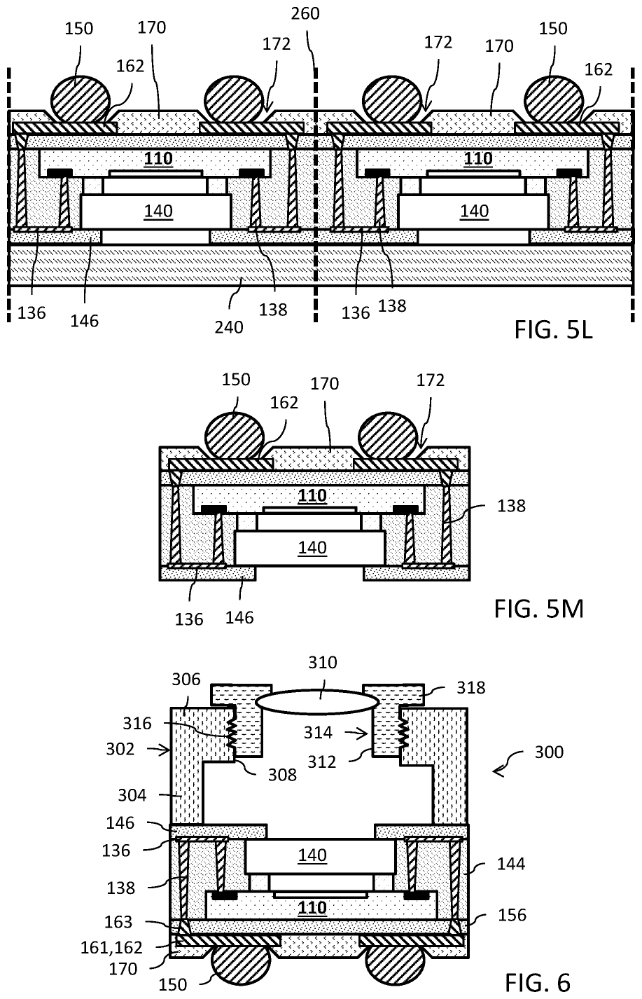

FIG. 6 shows a cross sectional diagram of an imaging sensor product utilizing the optical integrated circuit sensor device packaging configuration shown in FIGS. 4 and 5M. A lens assembly 300 is mounted to the passivation layer 146 of the optical integrated circuit sensor device package using an adhesive material. The lens assembly 300 comprises a frame 302 including sidewall legs 304 mounted to the passivation layer 146 and a front plate 306 with a central bore 308 that is female threaded. A lens 310 is secured within the central bore 312 of a cylindrical lens mount 314. The outer cylindrical surface 316 of the mount 314 is male threaded (to engage with the female thread of the central bore 308). A shoulder 318 of the mount 314 functions as a stop to set a maximum depth of threading engagement between the mount 314 and the frame 302.

While the invention has been illustrated and described in detail in the drawings and foregoing description, such illustration and description are considered illustrative or exemplary and not restrictive; the invention is not limited to the disclosed embodiments. Other variations to the disclosed embodiments can be understood and effected by those skilled in the art in practicing the claimed invention, from a study of the drawings, the disclosure, and the appended claims.

What is claimed is:

1. An integrated circuit package, comprising:
an integrated circuit device having a first side and a second side opposed to the first side, with an optical sensor and first electrical connection pads at said first side;
an optical element mounted to the first side of the integrated circuit device to extend over the optical sensor;
a body of laser direct structuring (LDS) encapsulating material which encapsulates the integrated circuit device and the optical element, said body having a first surface coplanar with an upper surface of the optical element and a second surface coplanar with the second side of the integrated circuit device;
wherein said body includes activated trace regions at the first surface, first activated via openings extending through the body from the first surface to the second surface, and second activated via openings extending into the body from the first surface to the first electrical connection pads;
first conductive lines at said activated trace regions;
first conductive vias at said first and second activated via openings in electrical connection with the first conductive lines;
a first passivation layer covering the first conductive lines, the first surface of the body and a portion of the optical element;
a second passivation layer covering the second surface of the body and the second side of the integrated circuit device; and
a redistribution layer (RDL) including second conductive lines and second conductive vias which extend through the second passivation layer to electrically connect the second conductive lines to the first conductive vias.

2. The integrated circuit package of claim 1, further comprising an adhesive spacer ring that surrounds the optical sensor and is positioned between a lower surface of the optical element and the first side of the integrated circuit device.

3. The integrated circuit package of claim 2, wherein said adhesive spacer ring is made of a bead of epoxy material.

4. The integrated circuit package of claim 1, wherein said first passivation layer includes an opening over a central region of the optical element that is optically aligned with the optical sensor.

5. The integrated circuit package of claim 1, wherein said RDL further includes pads extending from the second conductive lines.

6. The integrated circuit package of claim 5, further comprising solder balls attached to the pads for the RDL.

7. The integrated circuit package of claim 5, further comprising a solder mask layer covering the second passivation layer and including openings at locations of the pads for the RDL.

8. The integrated circuit package of claim 1, wherein said first conductive lines and said first conductive vias comprise metal plating at said activated trace regions and said first and second activated via openings.

9. A method, comprising:
mounting a plurality of integrated circuit devices in a spaced apart fashion to a support handle;
wherein an optical element is mounted to a first side of each integrated circuit device to extend over an optical sensor;
molding a laser direct structuring (LDS) encapsulation material to form a body that encapsulates the plurality of integrated circuit devices and the optical elements mounted thereto;
wherein a first surface of the body is coplanar with an upper surface of each of the optical elements;
laser defining activated trace regions on the first surface of the body;
laser drilling first activated via openings extending into the body from the first surface, said first activated via openings reaching electrical connection pads at the first side of the integrated circuit devices;
laser drilling second activated via openings extending into the body from the first surface to a depth which does not reach a second surface of the body in contact with the support handle;
plating conductive vias at the first and second activated via openings and plating conductive lines at the activated trace regions;
depositing a first passivation layer to cover the first surface of the body, the conductive lines and a portion of the upper surface of the upper surface of each of the optical elements;
removing the support handle to expose the second surface of the body and a second side of each integrated circuit device opposite the first side;
thinning the body from its second surface and each integrated circuit device from its second side to form a thinned surface at which a distal end of the conductive vias at the second activated via openings is exposed;
depositing a second passivation layer to cover the thinned surface; and
forming a redistribution layer (RDL) including second conductive lines and second conductive vias which extend through the second passivation layer to electrically connect the second conductive lines to the distal end of the conductive vias at the second activated via openings.

10. The method of claim 9, further comprising mounting the optical element to the first surface of the integrated circuit device using an adhesive spacer ring that surrounds the optical sensor.

11. The method of claim 9, wherein said LDS encapsulation material comprises a resin material infiltrated with laser activatable particles.

12. The method of claim 11, wherein laser defining and laser drilling activate said laser activatable particles at the activated trace regions and first and second activated via openings.

13. The method of claim 9, further comprising forming an opening in the first passivation layer to expose a central region of each optical element in optical alignment with the optical sensor of the integrated circuit device.

14. The method of claim 9, further comprising mounting a further handle to the first passivation layer before thinning.

15. The method of claim 9, wherein thinning comprises performing a back side grind on the second surface of the body and the second side of each integrated circuit device.

16. The method of claim 9, further comprising depositing a solder mask layer to cover the second passivation layer.

17. The method of claim 16, wherein forming the RDL further includes pads extending from the second conductive lines.

18. The method of claim 17, further comprising forming openings in the solder mask layer to expose the pads of the RDL.

19. The method of claim 18, further including mounting solder balls to the pads of the RDL.

20. The method of claim 9, further comprising performing a dicing operation to cut through the first passivation layer, thinned body and second passivation layer at locations between integrated circuit devices to produce a plurality of packages.

21. The method of claim 9, further comprising, before mounting the plurality of integrated circuit devices:
forming an integrated circuit wafer including a plurality of circuits;
mounting the integrated circuit wafer to a further support handle;
mounting the optical element over each circuit; and
dicing the integrated circuit wafer between circuits to produce said plurality of integrated circuit devices.
